(19) United States
(12) Patent Application Publication
(10) Pub. No.: US 2009/0008781 A1
(43) Pub. Date: Jan. 8, 2009

(54) SEMICONDUCTOR DEVICE

(75) Inventors: Bai-rou Ni, Taipei (TW); Fang-Yu Yeh, Taoyuan (TW); Yueh-Chuan Lee, Nantou Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ProMOS Technologies Inc., Hsinchu (TW)

(21) Appl. No.: 12/211,068

(22) Filed: Sep. 15, 2008

Related U.S. Application Data
(62) Division of application No. 11/163,121, filed on Oct. 5, 2005.
Application No. 11/163,121 is a division of application No. 10/249,368, filed on Apr. 3, 2003, now abandoned.

(30) Foreign Application Priority Data
Dec. 20, 2002 (TW) 91136785

(51) Int. Cl. H01L 29/51

(52) U.S. Cl. 257/754; 257/E29.162

(57) ABSTRACT

A semiconductor device structure includes a substrate, a first conductive layer over the substrate, a second conductive layer between the first conductive layer and the substrate and extending over the sidewalls of the first conductive layer, a dielectric layer between the second conductive layer and the substrate, a cap layer over the first conductive layer and the second conductive layer, and a liner layer on the sidewalls of the second conductive layer.

### CROSS-REFERENCE TO RELATED APPLICATION

This application is a divisional of an application Ser. No. 11/163,121, filed on Oct. 5, 2005, now pending, which is a divisional of a prior application Ser. No. 10/249,368, filed on Apr. 3, 2003, which claims the priority benefit of Taiwan application serial no. 91136785, filed on Dec. 20, 2002. The entirety of each of the above-mentioned patent applications is hereby incorporated by reference herein and made a part of this specification.

### BACKGROUND OF THE INVENTION

1. Field of Invention

The present invention relates to a method of manufacturing an integrated circuit. More particularly, the present invention relates to a semiconductor device and manufacturing method thereof.

2. Description of Related Art

Due to a high level of integration in deep sub-micron integrated circuits, dimensional parameters including line width, contact area, junction depth are all reduced. To improve device performance and lower resistor-capacitor transmission delay (RC-Delay), a layer of refractory metal silicide is often formed over the gate polysilicon layer inside a semiconductor device. The combination of the polysilicon and the refractory metal silicide layer is frequently called a polycide gate. Among the materials for forming the refractory metal silicide, tungsten silicide (WSiₓ) is the most general one. The polysilicon layer and the tungsten silicide layer are specifically referred to as a polysilicon tungsten silicide gate. The fabrication of a conventional polysilicon tungsten silicide gate is illustrated in the following description.

FIGS. 1A to 1D are schematic cross-sectional views showing the steps for manufacturing a conventional polysilicon tungsten silicide gate. As shown in FIG. 1A, a substrate 100 is provided. A gate dielectric layer 102 is formed over the substrate 100 and then a polysilicon layer 104 is formed over the gate dielectric layer 102. An ion implantation is carried out implanting different types of dopants into the polysilicon layer 104 so that the polysilicon layer 104 is divided into an N-type polysilicon layer 104a and a P-type polysilicon layer 104b.

As shown in FIG. 1B, a tungsten-rich tungsten silicide (WSiₓ, x<2.3) layer 106 is formed over the polysilicon layer 104 and then a cap layer 108 including a silicon nitride layer is formed over the tungsten silicide layer 106. Thereafter, a patterned photoresist layer 110 is formed over the cap layer 108.

As shown in FIG. 1C, the cap layer 108, the tungsten silicide layer 106, the polysilicon layer 104 and the gate oxide layer 102 are sequentially etched using the patterned photoresist layer 110 as a mask to form a gate stack structure 112.

As shown in FIG. 1D, a thermal oxidation process is carried out to form an oxide liner layer 114 on the sidewalls of the gate stack structure 112.

In the aforementioned method of forming the polysilicon tungsten silicide gate, the tungsten silicide layer 106 is exposed after the stack gate structure 112 is formed. Hence, the tungsten silicide layer 106 will react with oxygen to form tungsten oxide. Furthermore, in a high-temperature process including a thermal annealing or a thermal oxidation, the tungsten silicide layer 106 may undergo a phase transition that leads to some lateral extrusion (as shown in FIG. 1D). With line space getting smaller due to miniaturization, such extrusion may lead to a partial short circuit between the gate and a subsequently formed contact. Ultimately, overall performance of the device is affected.

To prevent the formation of lateral extrusion in the tungsten silicide layer, silicon content within the tungsten silicide layer is raised. In other words, a silicon-rich tungsten silicide (Silicon-rich WSiₓ, x≧2.3) is usually formed. However, the introduction of more silicon into the tungsten silicide layer will lead to higher sheet resistance in the gate. On the other hand, if the sheet resistance is reduced through increasing the thickness of the tungsten silicide layer, the gate will have a greater aspect ratio leading to greater difficulties in subsequent gate etching and self-aligned contact (SAC) etching process.

Moreover, if a gate having regions with different dopants is required, the aforementioned fabricating method often leads to the counter-diffusion of dopants. In other words, after implanting different dopants into the polysilicon layer to form the N-type polysilicon layer and the P-type polysilicon layer, different types of dopants may diffuse into each other through the tungsten silicide layer when the silicon nitride cap layer is formed in a high-temperature process. Hence, overall performance of the device is adversely affected.

### SUMMARY OF THE INVENTION

Accordingly, one object of the present invention is to provide a semiconductor device and manufacturing method thereof that can prevent the formation of lateral extrusion in the metal silicide layer and the counter-diffusion of dopants leading to a higher level of integration and an improved device performance.

To achieve these and other advantages and in accordance with the purpose of the invention, as embodied and broadly described herein, the invention provides a method of manufacturing a semiconductor device. The method includes the following steps. First, an insulating layer is formed over a substrate. Thereafter, the insulating layer is patterned to form a first opening therein. A first conductive layer is formed over the substrate such that the first opening is only partially filled. Next, a second conductive layer is formed over the substrate such that the first opening is now completely filled. The first conductive layer and the second conductive layer outside the first opening are removed to expose the insulating layer. A portion of the first conductive layer and the second conductive layer are partially etched back so that the surface of the first conductive layer and the second conductive layer are below the surface of the insulating layer, thereby forming a second opening. A cap layer is formed inside the second opening. Finally, the insulating layer is removed and a liner layer is formed on the sidewalls of the first conductive layer.

In the aforementioned method of fabricating the semiconductor device, after forming the first opening in the insulating layer but before filling the first opening with the first conductive layer, a cleaning process may also be included. Furthermore, the first conductive layer can be fabricated using a material including polysilicon and the second conductive layer can be fabricated using a material including refractory metal silicide.

In this invention, the refractory metal silicide layer is enclosed within the polysilicon layer so that the refractory metal silicide layer is prevented from contacting oxygen to form metal oxide and producing lateral extrusion in a subsequent high-temperature treatment process. In other words, the process window of a subsequent self-aligned contact etching operation is broadened and that a refractory metal silicide compound with less silicon content can be employed to reduce resistance and improve device performance.

This invention also provides a method of manufacturing a polysilicon silicide gate structure. The method includes the following steps. First, an insulating layer is formed over a substrate. Thereafter, the insulating layer is patterned to form a plurality of first openings that exposes the substrate and then a gate dielectric layer is formed over the exposed substrate. After forming a polysilicon over the substrate partially filling the first openings, a refractory metal silicide layer is formed over the substrate completely filling the first openings. The polysilicon layer and the refractory metal silicide layer outside the first openings are removed to expose the insulating layer. Etching back a portion of the polysilicon layer and the refractory metal silicide layer so that the surface of the polysilicon layer and the refractory metal silicide layer is below the surface of the insulating layer, thereby forming a plurality of second openings. Next, a cap layer is formed inside the second openings. Finally, the insulating layer is removed to form a plurality of polysilicon silicide gate structures. Finally, a liner layer is formed on the sidewalls of the polysilicon layer.

In the aforementioned method of fabricating the polysilicon silicide gate structures, after forming the polysilicon layer over the substrate but before forming the refractory metal silicide layer, an implant process may be included to form a first conductive type polysilicon layer and a second conductive type polysilicon layer. Furthermore, after removing the polysilicon layer and the refractory metal silicide layer outside the first openings to expose the insulating layer, the first conductive type polysilicon layer and the second conductive type polysilicon layer are located in different first openings.

In addition, in the process of removing a portion of the polysilicon layer and refractory metal silicide layer outside the first openings, the refractory metal silicide layer is cut up so that the first conductive type polysilicon layer and the second conductive type polysilicon layer are isolated from each other. Hence, when the cap layer is subsequently formed, counter-diffusion between the dopants in the first conductive type polysilicon layer and the dopants in the second conductive type polysilicon layer is prevented.

In this invention, the refractory metal silicide layer is enclosed within the polysilicon layer so that the refractory metal silicide layer is prevented from contacting oxygen to form metal oxide and producing lateral extrusion in a subsequent high-temperature treatment process. With an improved gate structural profile, the process window of a subsequent self-aligned contact etching operation is broadened and that a refractory metal silicide compound with less silicon content can be employed to reduce resistance and improve device performance.

This invention also provides a semiconductor device structure. The semiconductor device structure includes a substrate, a first conductive layer over the substrate, a second conductive layer between the first conductive layer and the substrate and extending over the sidewalls of the first conductive layer, a dielectric layer between the second conductive layer and the substrate, a cap layer over the first conductive layer and the second conductive layer and a liner layer on the sidewalls of the second conductive layer.

In the aforementioned semiconductor device structure, the first conductive layer is a refractory metal silicide layer and the second conductive layer is a polysilicon layer. Using the polysilicon layer to enclose the refractory metal silicide layer is able to prevent the refractory metal silicide from contacting oxygen and produce oxide material. Moreover, enclosing the refractory metal silicide layer also prevents the formation of lateral extrusion when subjected to high-temperature thermal treatment. Hence, the process window of a subsequent self-aligned contact etching operation is broadened and that a refractory metal silicide compound with less silicon content can be employed to reduce resistance and improve device performance.

It is to be understood that both the foregoing general description and the following detailed description are exemplary, and are intended to provide further explanation of the invention as claimed.

### BRIEF DESCRIPTION OF THE DRAWINGS

FIGS. 1A to 1D are schematic cross-sectional views showing the steps for manufacturing a conventional polysilicon tungsten silicide gate.

FIGS. 2A to 2H are schematic cross-sectional views showing the steps for manufacturing a semiconductor device according to one preferred embodiment of this invention.

FIG. 3 is a schematic cross-sectional view of a semiconductor device according to this invention.

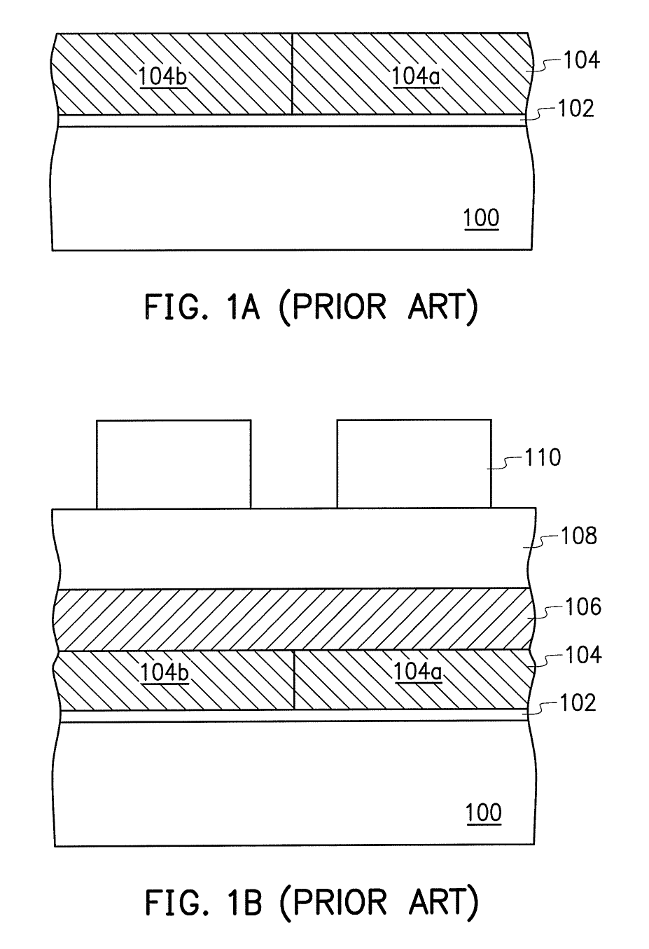

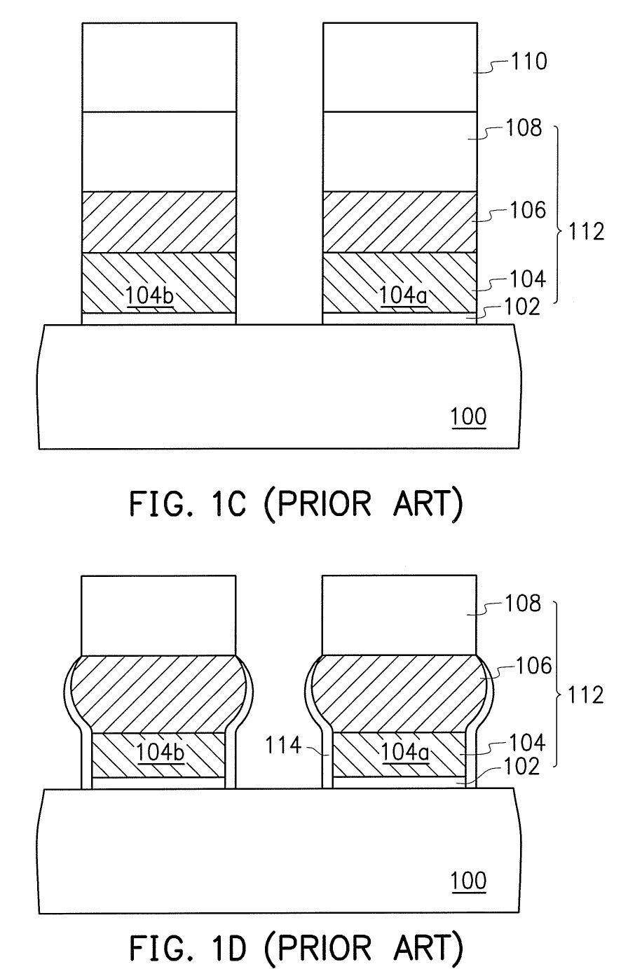

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

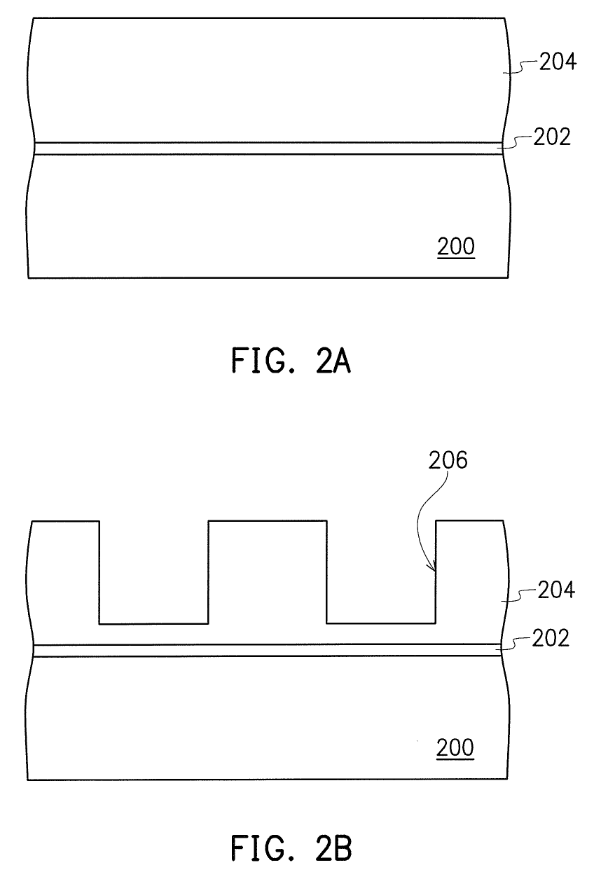

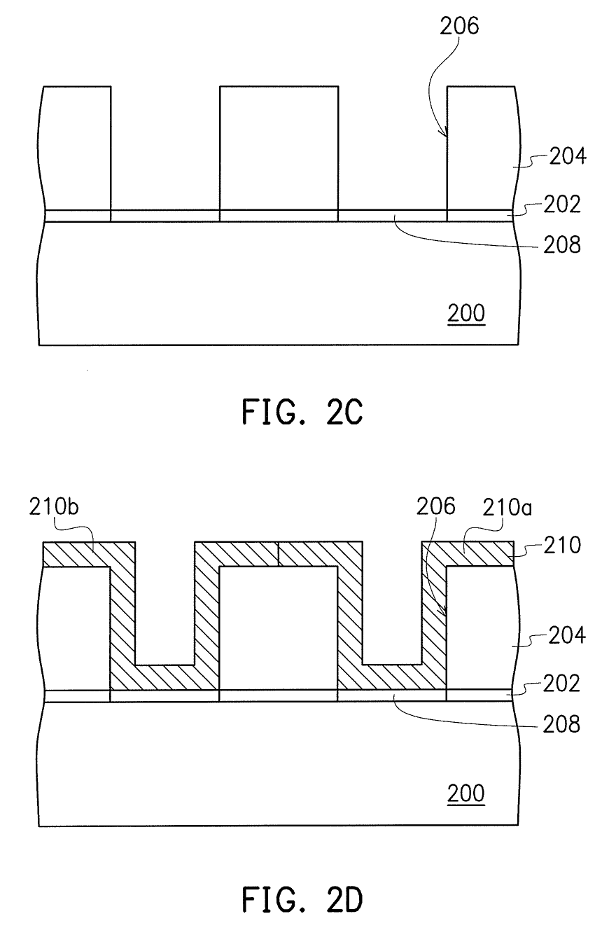

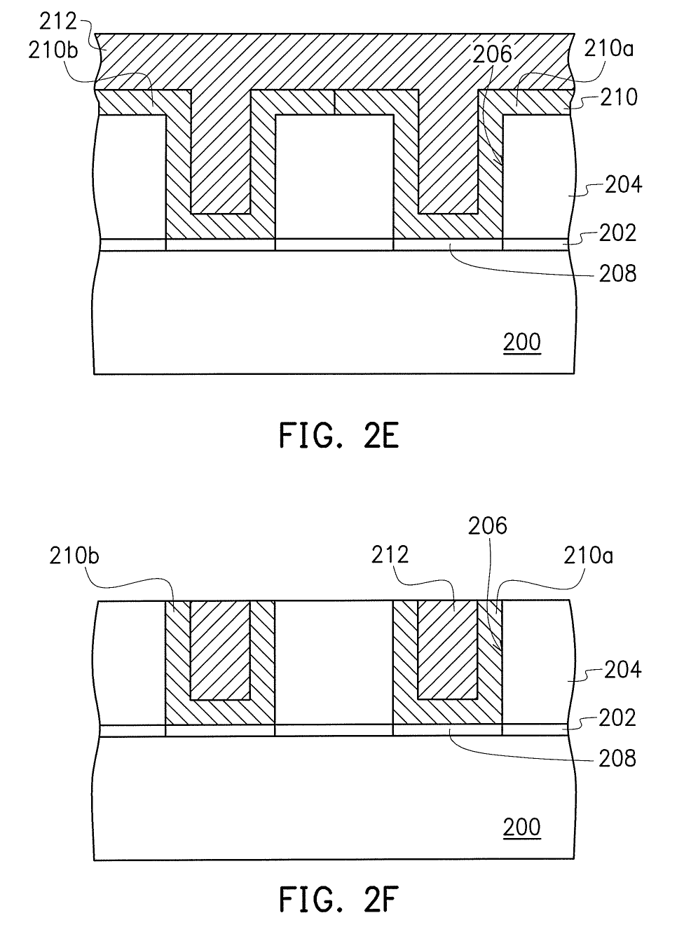

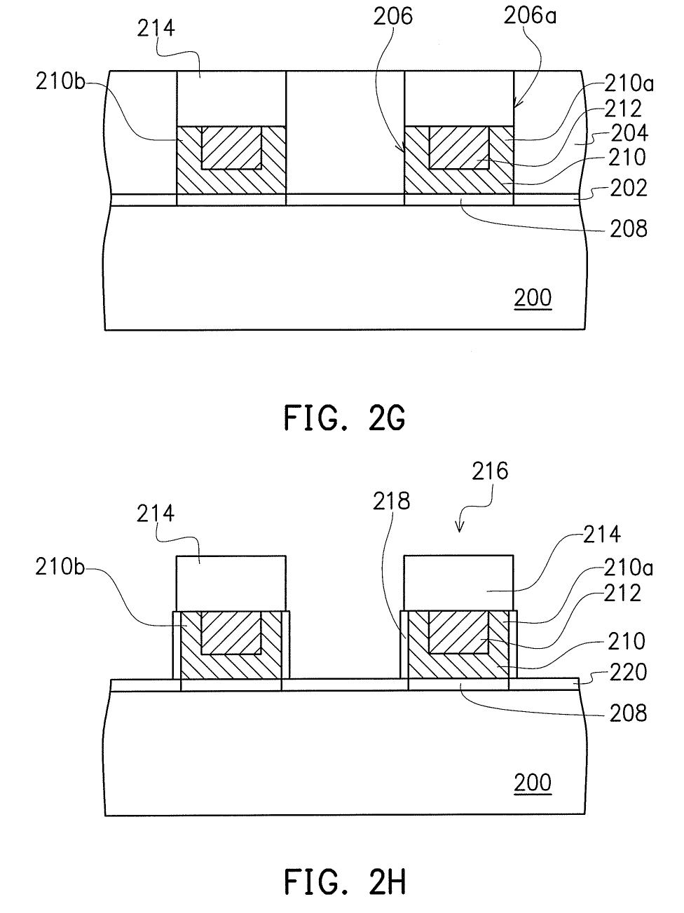

FIGS. 2A to 2H are schematic cross-sectional views showing the steps for manufacturing a semiconductor device according to one preferred embodiment of this invention. As shown in FIG. 2A, a substrate 200 is provided. The substrate 200 is, for example, a silicon substrate. A sacrificial layer 202 and an insulating layer 204 are sequentially formed over the substrate 200. The sacrificial layer 202 can be a silicon oxide layer formed, for example, by conducting a thermal oxidation. The insulating layer 204 is fabricated using a material having an etching rate that differs from subsequently formed polysilicon, refractory metal silicide, and cap layer materials. The insulating layer 204 can be a silicon oxide layer formed, for example, by conducting a chemical vapor deposition using tetra-ethyl-ortho-silicate (TEOS)/ozone (O3).

As shown in FIG. 2B, a patterned photoresist layer (not shown) is formed over the insulating layer 204. Thereafter, using the patterned photoresist layer as a mask, the insulating layer 204 is etched to form openings 206. The openings 206 are not deep enough to expose the substrate 200 below. In other words, a layer of insulating material still covers the substrate 200 inside the openings 206. The insulating layer 204 is etched by conducting a dry etching including a reactive ion etching. After the etching operation, the patterned photoresist layer is removed.

As shown in FIG. 2C, a wet cleaning step is carried out to remove residual insulating material over the substrate 200 inside the openings 206. Etching solutions used for conducting the wet cleaning operation include, for example, a sulfuric-peroxide mixture (SPM) and diluted hydrofluoric acid (DHF). Note that thickness of the insulating layer 204 will be slightly reduced after the wet cleaning operation.

A gate dielectric layer 208 is formed over the substrate 200 at the bottom of the openings 206. The gate dielectric layer 208 is fabricated using a material selected from a group consisting of silicon oxide, silicon oxy-nitride and other high dielectric constant insulating materials (with K>4). The gate dielectric layer 208 is formed, for example, by conducting a thermal oxidation or a chemical vapor deposition.

As shown in FIG. 2D, a conductive layer 210 is formed over the substrate 200 partially filling the openings 206. The conductive layer 210 can be a polysilicon layer formed, for example, by conducting a low-pressure chemical vapor deposition. Different types of dopants are implanted into the conductive layer 210 so that an N-type conductive layer 210a and a P-type conductive layer 210b are formed. Implanting different types of dopants into the conductive layer 210 includes the following steps. First, a patterned mask layer (not shown) that exposes the areas for forming the N-type conductive layer 210a is formed over the substrate 200. After implanting N-type dopants into the exposed conductive layer 210 using the patterned mask layer as an implant mask to form the N-type conductive layer 210a, the patterned mask layer is removed. Thereafter, another patterned mask layer (not shown) that exposes the areas for forming the P-type conductive layer 210b is formed over the substrate 200. After implanting P-type dopants into the exposed conductive layer 210 using the patterned mask layer as an implant mask to form the P-type conductive layer 210b, the patterned mask layer is removed.

As shown in FIG. 2E, a refractory metal silicide layer 212 is formed over the substrate 200 completely filling the openings 206. The refractory metal silicide layer 212 is formed, for example, by conducting a low-pressure chemical vapor deposition (LPCVD). The refractory metal silicide layer 212 is fabricated using a material including, for example, tungsten silicide, nickel silicide, cobalt silicide, titanium silicide, molybdenum silicide, platinum silicide or palladium silicide. In this embodiment, tungsten silicide with a chemical formula WSiₓ where x<2.3, also referred to as a tungsten-rich tungsten silicide, is used.

As shown in FIG. 2F, a portion of the conductive layer 210 and the refractory metal silicide layer 212 outside the openings 206 are removed to expose the insulating layer 204. In other words, only the conductive layer 210 and the refractory metal silicide layer 212 inside the openings 206 is retained. The conductive layer 210 and the refractory metal silicide layer 212 outside the openings 206 are removed, for example, by chemical-mechanical polishing. After the polishing process, the N-type conductive layer 210a and the P-type conductive layer 210b are detached from each other and hence located within different openings 206.

As shown in FIG. 2G, the polysilicon layer 210 and the refractory metal silicide layer 212 inside the openings 206 are etched back such that the surface of the polysilicon layer 210 and the refractory metal silicide layer 212 is below the surface of the insulating layer 204. Ultimately, openings 206a are formed in the insulating layer 204. Thereafter, a cap layer 214 is formed inside the openings 206a. The cap layer 214 is fabricated using a material including silicon nitride. The cap layer 214 is formed, for example, by conducting a chemical vapor deposition to form a silicon nitride layer and then chemical-mechanical polishing the silicon nitride layer to remove the silicon nitride material outside the openings 206a to expose the surface of the insulating layer 204.

As shown in FIG. 2H, the insulating layer 204 and the sacrificial layer 202 over the substrate 200 is removed to form gate structures 216. The insulating layer 204 and the sacrificial layer 202 is removed, for example, by wet etching using a buffered oxide etchant (BOE) containing a mixture of hydrofluoric acid (HF) and ammonium fluoride (NH4F) as an etchant. Thereafter, a thermal treatment including a thermal annealing process or a thermal oxidation is conducted to form a liner layer 218 on the sidewalls of the polysilicon layer 210. The thermal treatment is capable of repairing some of the lattice defects in the conductive layer 210 created after ion implantation. To complete the fabrication of the semiconductor device, other processes for forming spacers on the sidewalls of the gate structures, forming source/drain regions in the substrate on each side of the gate structures and forming the inter-layer dielectric and the contacts are conducted. Since conventional methods are used, detailed description of these processes is omitted here.

In the process of fabricating the semiconductor device, a portion of the polysilicon layer 210 and the tungsten silicide layer (the refractory metal silicide layer 212) outside the first openings is removed. Therefore, the tungsten silicide layer (the refractory metal silicide layer 212) is cut up so that the N-type polysilicon layer 210a and the P-type polysilicon layer 210b are within different openings 206. When the cap layer 214 is subsequently formed, counter-diffusion between the dopants in the N-type polysilicon layer 210a and the dopants in the P-type polysilicon layer 210b is prevented.

In addition, the tungsten silicide layer (the refractory metal silicide layer 212) is enclosed within the polysilicon layer 210 so that the tungsten silicide (the refractory silicide layer 212) is prevented from contacting oxygen to form metal oxide and producing lateral extrusion in a subsequent high-temperature treatment process. With an improved gate structural profile, the process window of a subsequent self-aligned contact etching operation is broadened and that a refractory metal silicide compound with less silicon content can be employed to reduce resistance and improve device performance.

Furthermore, after etching the polysilicon layer 210 and the refractive metal silicide layer 212 inside the openings 206 to reduce their surface to a level below the surface of the insulating layer 204, a second etching process may be carried out. This time, the polysilicon layer 210 is etched to a level below the surface of the refractory metal silicide layer 212. In the second etching step, an etchant having a higher etching rate on polysilicon 210 than both the refractory metal silicide layer 212 and the insulating layer 204 must be chosen. For example, a mixture containing both hydrofluoric acid (HF) and nitric acid (HNO3) can be used in the second etching operation. When the cap layer 214 is subsequently formed over the refractory metal silicide layer 212 and the polysilicon layer 210, a portion of the cap layer 214 will cover the sidewalls of the refractory metal silicide layer. Since the cap layer is a silicon nitride layer, the cap layer has an etching rate that differs from conventional inter-layer dielectric including silicon oxide and borophosphosilicate glass (BPSG). Moreover, the cap layer may also serve as an etching stop layer for forming contacts. Therefore, a greater process window is permitted with regard to the possible short circuit between the gate and the conductive portion of the contact.

Obviously, the aforementioned embodiment is applied to fabricate gate structures. However, the method can be applied to the fabrication of other semiconductor devices including the word lines of memory device, the gate of the memory device, the metal-oxide-semiconductor transistor or metallic interconnects.

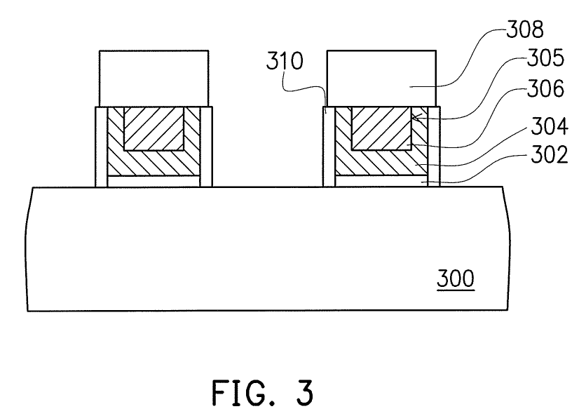

FIG. 3 is a schematic cross-sectional view of a semiconductor device according to this invention. As shown in FIG. 3, the semiconductor device structure of this invention includes a substrate 300, a dielectric layer 302, a first conductive layer 304, a second conductive layer 306, a cap layer 308 and a liner layer 310.

The dielectric layer 302 is set up over the substrate 300. The dielectric layer 302 is fabricated using a material selected from a group consisting of silicon oxide, silicon oxy-nitride or other high dielectric constant insulating materials.

The first conductive layer 304 is positioned over the dielectric layer 302 and fabricated from a material including polysilicon. The conductive layer 304 has a U-shaped sectional profile with an opening 305 therein.

The second conductive layer 306 is located within the opening 305 of the first conductive layer 304. The second conductive layer 306 is fabricated using a refractive metal silicide compound selected from a group consisting of tungsten silicide, nickel silicide, cobalt silicide, titanium silicide, molybdenum silicide, platinum silicide and palladium silicide.

The cap layer 308 is positioned over the first conductive layer 304 and the second conductive layer 306. The cap layer 308 is fabricated using silicon nitride, for example.

The liner layer 310 is formed on the sidewalls of the first conductive layer 304. The liner layer 310 material, for example, is silicon oxide or silicon nitride.

In the aforementioned semiconductor device structure, the refractory metal silicide layer (the second conductive layer 306) is enclosed within the polysilicon layer (the first conductive layer 304). Hence, the tungsten silicide (the second conductive layer 306) is prevented from contacting oxygen to form metal oxide and producing lateral extrusion in a subsequent high-temperature treatment process. With an improved conductive stack structural profile, the process window of a subsequent self-aligned contact etching operation is broadened and that a refractory metal silicide compound with less silicon content can be employed to reduce resistance and improve device performance.

Obviously, the refractory metal silicide layer (the second conductive layer 306) may protrude from the opening 305 in the polysilicon layer (the first conductive layer 304). In other words, the polysilicon layer (the first conductive layer 304) only covers a portion of the sidewalls of the refractory metal silicide layer (the second conductive layer 306) so that the upper section of the sidewalls is enclosed by the cap layer 308. Since the cap layer 308 is typically a silicon nitride layer that has an etching rate that differs from most inter-layer dielectric including silicon oxide and borophosphosilicate glass, the cap layer 308 can serve as an etching stop layer in the subsequent fabrication of contacts. Therefore, a greater process window is permitted with regard to the possible short circuit between the gate and the conductive portion of the contact.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device structure, comprising:
a substrate;
a dielectric layer over the substrate;
a first conductive layer over the dielectric layer, wherein the first conductive layer has a first opening;
a second conductive layer inside the opening in the first conductive layer;
a cap layer over the first conductive layer and the second conductive layer; and
a liner layer on the sidewalls of the first conductive layer.

2. The semiconductor device structure of claim 1, wherein the first conductive layer has a U-shaped cross-section.

3. The semiconductor device structure of claim 1, wherein the first conductive layer includes a polysilicon layer.

4. The semiconductor device structure of claim 1, wherein the second conductive layer includes a refractory metal silicide layer.

5. The semiconductor device structure of claim 1, wherein the cap layer includes a silicon nitride layer.

6. The semiconductor device structure of claim 1, wherein the second conductive layer protrudes above the opening in the first conductive layer and that the cap layer covers the upper sidewalls of the second conductive layer.
